(19) United States
(12) Patent Application Publication
(10) Pub. No.: US 2007/0194453 A1
(43) Pub. Date: Aug. 23, 2007

(54) Integrated circuit architecture for reducing interconnect parasitics

(76) Inventors: Kanad Chakraborty, Bridgewater, NJ (US); Bingxiong Xu, Edison, NJ (US); Xingling Zhou, Allentown, PA (US)

Correspondence Address: Ryan, Mason & Lewis, LLP, 90 Forest Avenue, Locust Valley, NY, 11560, US

(21) Appl. No.: 11/341,747

(22) Filed: Jan. 27, 2006

(51) Int. Cl. H01L 23/52; H01L 23/48; H01L 29/40

(52) U.S. Cl. 257/777

(57) ABSTRACT

An integrated circuit includes a first semiconductor chip including one or more circuits thereon performing substantially core logic functions, the first semiconductor chip including multiple signal pads for providing electrical connection to the one or more circuits. The integrated circuit further includes at least a second semiconductor chip including one or more circuits thereon performing substantially input/output interface functions, the second semiconductor chip including multiple signal pads for providing electrical connection to the one or more circuits on the first semiconductor chip. The signal pads on the second semiconductor chip are substantially aligned with and electrically connected to corresponding signal pads on the first semiconductor chip. The first and second semiconductor chips are mutually functionally dependent on one another, such that at least a portion of at least one of the one or more circuits on the first semiconductor chip utilizes at least a portion of at least one of the one or more circuits on the second semiconductor chip, and vice versa. The first and second semiconductor chips are formed using first and second semiconductor fabrication processes, respectively.

### FIELD OF THE INVENTION

The present invention relates generally to semiconductor devices, and more particularly relates to architectures for reducing the effects of interconnect parasitics in an integrated circuit device.

### BACKGROUND OF THE INVENTION

As a consequence of the recent trend to push the lateral integration of systems on a chip (SoC), modern advanced application-specific integrated circuit (ASIC) design has focused largely on interconnects. This is due primarily to the fact that interconnects have become a dominant factor in determining circuit performance and reliability in deep submicron designs. Signal integrity problems, such as, for example, crosstalk noise, current x resistance (IR)-drop and coupling-induced delay variation are becoming increasingly more significant due at least in part to the larger parasitics associated with an increasing number of interconnects and an increased circuit density in a given integrated circuit device. At the same time, the complexity of implementing large systems on a chip is becoming increasingly burdensome on designers.

There have been various attempts aimed at reducing the effect of interconnect parasitics in an integrated circuit. From a circuit level standpoint, known methodologies for addressing signal integrity problems locally include inserting one or more buffers in a given signal path, driver sizing, wire spacing and wiring sizing optimizations, etc. However, most circuit level solutions typically consume significant routing resources and usually result in a substantial increase in the number of iterations in the physical design loop, thereby undesirably increasing the design cycle of the integrated circuit and delaying time to market.

Integrated circuit chip level solutions for reducing the effects of interconnect parasitics include planar integration of functional blocks and better placements of these functional blocks in the chip in order to optimize the distance of global routing. Known package level solutions attempting to minimize the effects of interconnect parasitics in an integrated circuit typically involve reducing the overall length of interconnects in the integrated circuit by employing die stacking methodologies to implement system in a package (SiP) designs. Both chip level and package level solutions, however, generally involve planar integration of functional blocks within the same chip, and therefore do not address signal integrity problems associated with global on-chip interconnects in advancing design technologies. Consequently, with chip level and package level solutions, a designer must be careful when sending global signals and/or clock signals to respective corners of the chip simultaneously.

Accordingly, there exists a need for an improved integrated circuit architecture for reducing the effects of interconnect parasitics, which does not suffer from one or more of the problems exhibited by conventional integrated circuit architectures.

### SUMMARY OF THE INVENTION

The present invention meets the above-noted need by providing an improved integrated circuit architecture for reducing the effects of interconnect parasitics in an integrated circuit device and thereby improving circuit performance and reliability, particularly in deep submicron SoC designs. To accomplish this, in accordance with an illustrative embodiment of the invention, components or other circuits are distributed into at least two semiconductor chips, each semiconductor chip being used to handle different functional tasks. For example, a first chip, which may be referred to as a core chip, includes core components or other core circuits which will work cooperatively together as a system for handling core-related functional tasks. Similarly, a second chip, which may be referred to as an input/output (IO) chip, includes IO components or other IO circuits which will work cooperatively together for handling IO-related functional tasks. In this manner, the separate functional tasks can be independently optimized for improving overall integrated circuit performance.

In accordance with one aspect of the invention, an integrated circuit includes a first semiconductor chip including one or more circuits thereon performing substantially core logic functions, the first semiconductor chip including multiple signal pads for providing electrical connection to the one or more circuits. The integrated circuit further includes at least a second semiconductor chip including one or more circuits thereon performing substantially input/output interface functions, the second semiconductor chip including multiple signal pads for providing electrical connection to the one or more circuits on the second semiconductor chip. The signal pads on the second semiconductor chip are substantially aligned with and electrically connected to corresponding signal pads on the first semiconductor chip. The first and second semiconductor chips are mutually functionally dependent on one another, such that at least a portion of at least one of the one or more circuits on the first semiconductor chip utilizes at least a portion of at least one of the one or more circuits on the second semiconductor chip, and vice versa. The first and second semiconductor chips are formed using first and second semiconductor fabrication processes, respectively.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a cross-sectional view depicting an exemplary integrated circuit device, formed in accordance with one embodiment of the present invention.

FIG. 2 is a top plan view illustrating an exemplary input/output chip which may be employed in the integrated circuit device shown in FIG. 1, in accordance with an embodiment of the present invention.

FIG. 3 is a top plan view illustrating an exemplary core logic chip which may be employed in the integrated circuit device shown in FIG. 1, in accordance with an embodiment of the present invention.

FIG. 4 is a cross-sectional view depicting an exemplary packaged integrated circuit device, formed in accordance with an embodiment of the present invention.

### DETAILED DESCRIPTION OF THE INVENTION

The present invention will be described herein in the context of an illustrative SoC integrated circuit architecture. It should be understood, however, that the present invention is not limited to this or any other particular integrated circuit architecture and/or application. Rather, the invention is more generally applicable to techniques for providing an improved integrated circuit architecture for reducing the effects of interconnect parasitics in an integrated circuit device and thereby improve circuit performance and reliability, particularly in deep submicron SoC designs.

FIG. 1 is a cross-sectional view depicting an exemplary integrated circuit device 100, formed in accordance with one embodiment of the present invention. The integrated circuit device 100 comprises a first semiconductor chip 102 and at least a second semiconductor chip 104. Each of the semiconductor chips are preferably formed of silicon, and may therefore be referred to herein as silicon chips, although alternative semiconductor materials may also be employed, such as, for example, germanium, gallium arsenide, etc. The first chip 102 is preferably flipped upside down and placed on top of the second chip 104, as shown, so that upper surfaces of the first and second chips 102, 104 face one another, as in a standard flip-chip arrangement. In this configuration, the first and second chips 102, 104 are preferably electrically interconnected by way of one or more solder bumps 106, or an alternative substantially vertical connection arrangement, so as to reduce interconnect parasitics in the integrated circuit device 100. It is to be appreciated, however, that other stacked die configurations are similarly contemplated by the present invention.

During packaging of the integrated circuit device 100, the second chip 104 may be attached to a package substrate 108, using, for example, a solder bond or an epoxy bond between a lower surface of the second chip 104 and an upper surface of the package substrate 108, although alternative die attachment means for fixedly attaching the second chip 104 to the package substrate 108 are contemplated by the invention, as will be understood by those skilled in the art. The package substrate 108 may be formed of various known substantially rigid materials, including, but not limited to, ceramic, plastic, laminate, etc. Package substrate 108 preferably comprises a leadframe including a plurality of pins 110, or an alternative connection structure (e.g., ball grid array (BGA)), for providing external electrical connection to the integrated circuit device 100. Bond wires 112, or an alternative connection arrangement, may be used to connect the pins 110 in the leadframe or BGA to corresponding bond pads 114 formed on the upper surface of the second chip 104, such as by using a standard wire bonding process. The first chip 102 is preferably not connected to the leadframe or BGA, and therefore need not include bond pads.

A primary aspect of the integrated circuit architecture of the invention is that components or other circuits of a given system design are beneficially distributed into two or more semiconductor chips, as shown, with each chip comprising one or more circuit components or other that are functionally related to one another. For example, the system design may include a plurality of circuit components for performing primarily input/output (IO) functions, such as, but not limited to, analog-to-digital (AD) conversion, digital-to-analog (DA) conversion, serial-to-parallel conversion, parallel-to-serial conversion, IO buffering, clock generation, reference voltage generation, etc. These circuit components may be placed on an IO chip (e.g., second chip 104) including a plurality of bond pads providing external connection to the IO chip. Likewise, the system design may also include a plurality of circuit components for performing primarily core logic functions, such as, but not limited to, digital signal processing (DSP), timing control, algorithmic logic (AND, OR, NOT functions), etc. These circuit components may be placed on a core logic chip (e.g., first chip 102).

Since the system design is distributed into two or more semiconductor chips, each of which may be fabricated using different process technologies, the chips can be independently optimized according to the type of related functional circuit components or other circuits included thereon. For instance, IO circuit components are generally analog in nature and consume significantly more power compared to core logic circuitry. Consequently, power and ground connections employed on the IO chip may be formed wider compared to power and ground connections employed on the core logic chip so as to reduce IR drops and other signal integrity problems. This also enables the Preferably, power supply connections to the IO chip and to the core logic chip are separate. In fact, the core logic circuitry typically uses a supply voltage which is lower than the supply voltage used for the IO chip. In one embodiment of the invention, the core logic chip voltage supply is preferably about 1.0 volt and the IO chip voltage supply is about 3.3 volts, although the invention is not limited to any particular levels for the respective voltage supplies. By separating the power and ground supplies for the two chips, substrate noise often generated by digital logic circuitry on the core logic chip can be more easily isolated so as to avoid undesirably affecting analog circuitry on the IO chip. Core logic circuitry also scales more easily with processing technology, and thus the size of the core logic chip, which preferably only includes core logic circuitry, can be more easily optimized for size compared to the IO chip.

Unlike in SiP integrated circuit architectures employing stacked die arrangements, wherein each die comprises a self-contained, independently functioning system, the first and second chips 102, 104 in the exemplary integrated circuit device 100 do not function independently but rather are mutually functionally dependent on one another. Specifically, at least a portion of one or more of the circuit components on the first chip 102 utilizes at least a portion of one or more of the circuit components on the second chip 104, and vice versa, such that one chip does not fully function without the other chip. Thus, the two chips 102, 104 work cooperatively as a system.

Since the integrated circuit device 100 preferably employs a substantially vertical connection arrangement between the two chips 102, 104, interconnect routing between IO functional components and core logic functional components of the overall system design can be significantly reduced. Accordingly, the problems associated with such interconnect routing, including, but not limited to, crosstalk, routing congestion, etc., will also be advantageously reduced.

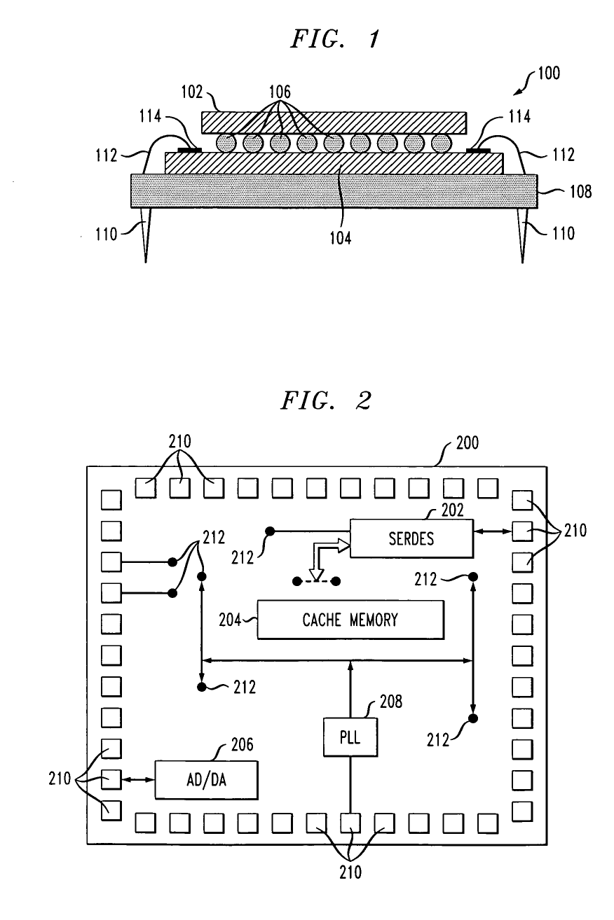

FIG. 2 is a top plan view illustrating an exemplary IO chip 200 formed in accordance with one embodiment of the invention. The IO chip, which may be employed as the second chip 104 in the illustrative integrated circuit device 100 shown in FIG. 1, comprises a plurality of IO functional blocks, including, but not limited to, a serializer/deserializer (SERDES) 202, cache memory 204, AD/DA converter 206 and a phase-locked loop (PLL) 208. One or more of the IO functional blocks may be connected to corresponding bond pads 210, as needed, for providing external electrical connection to and/or from the respective IO functional blocks. As previously described, connection between the IO chip 200 and a core logic chip (e.g., first chip 102 shown in FIG. 1) is preferably made via one or more solder bumps 212, or an alternative substantially vertical connection arrangement (e.g., conductive studs, etc.). The solder bumps 212 are placed on the IO chip 200 so as to be substantially aligned with corresponding signal pads on the core logic chip. This architecture, which enables signals to pass between the IO functional blocks on the IO chip 200 and core logic blocks on the core logic chip through substantially vertical connections, significantly reduces global interconnect wiring on the core logic chip and, accordingly, reduces signal integrity problems (e.g., crosstalk, IR drops, etc.) commonly associated therewith.

The IO functional blocks (e.g., 202, 204, 206, 208) included on the IO chip 200 are preferably common IO building blocks shared by various core logic circuit designs. Thus, the IO chip 200, in accordance with an aspect of the invention, can beneficially serve as a platform for handling generic IO interface functions common to a given system design. The IO chip can be reused for various system designs. By replacing the core logic chip connected to a given IO chip with one of a plurality of other semiconductor chips having a functionality different than that of the core logic chip, a different overall functionality can be achieved in the integrated circuit. This integrated circuit architecture thus enables circuit designers to concentrate their efforts on the core logic portion of the system design rather than on the IO interface portion of the system, thereby advantageously reducing cost, reducing design resources, and facilitating a shorter time-to-market compared to standard design practices.

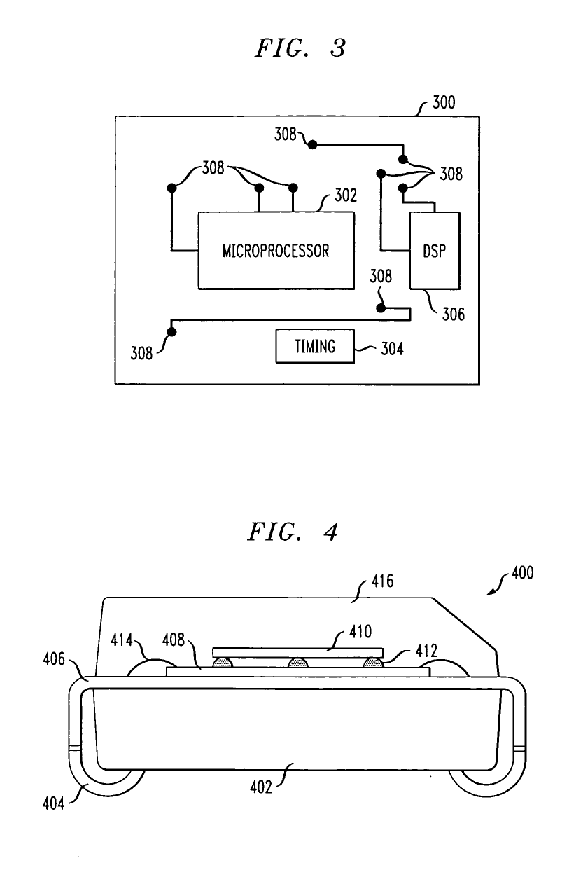

FIG. 3 is a top plan view illustrating an exemplary core logic chip 300 formed in accordance with one embodiment of the invention. The core logic chip, which may be employed as the first chip 102 in the illustrative integrated circuit device 100 shown in FIG. 1, comprises a plurality of core logic functional blocks, including, but not limited to, a microprocessor 302, a timing and control block 304 and a DSP core 306. Connection between the core logic chip 300 and an IO chip (e.g., second chip 104 shown in FIG. 1) is preferably made via one or more solder bumps 308, or an alternative substantially vertical connection arrangement (e.g., conductive studs, etc.). The solder bumps 308 are placed on the core logic chip 300 so as to be substantially aligned with corresponding signal pads on the IO chip. This architecture, which enables signals to pass between the IO functional blocks on the IO chip 200 (see FIG. 2) and core logic functional blocks on the core logic chip 300 through substantially vertical connections, significantly reduces global interconnect wiring on the core logic chip and the signal integrity problems (e.g., crosstalk, IR drops, etc.) commonly associated therewith, as previously stated.

Another benefit of the integrated circuit architecture of the present invention is that state-of-the-art foundry services are costly and not all circuits in the system benefit from such advanced processing. For example, digital logic circuitry, as may be included on the core logic chip, typically scales far more easily with advances in processing technology than the IO chip which comprises primarily analog circuitry. Consequently, using the techniques of the present invention set forth herein, the core logic chip may be fabricated using one process technology and the IO chip can be fabricated using another, less expensive process technology.

FIG. 4 is a cross section illustrating an exemplary packaged integrated circuit device 400 which incorporates the techniques of the present invention described herein, in accordance with another aspect of the invention. The packaged integrated circuit device 400 preferably comprises a die-attachment substrate 402 including a plurality of electrical contacts 404 forming at least part of a leadframe 406. The electrical contacts 404 provide external electrical connection to the packaged integrated circuit device 400. A first semiconductor chip 408 (e.g., IO chip) is attached to the die-attachment substrate 402, such as by using standard die attachment means (e.g., eutectic die attachment). A second semiconductor chip 410 (e.g., core logic chip) is preferably connected to the first chip 408 using a plurality of solder balls 412, or an alternative substantially vertical connection arrangement, as previously described. The connection arrangement between the first and second chips preferably provides not only electrical connection between various functional blocks residing on the respective chips, but also provides mechanical support for the second chip. Bond pads formed on the first chip 408 are connected to corresponding electrical contacts 404 of the leadframe 406 using bond wires 414, or alternative connection means.

An encapsulant material 416 preferably encloses the first and second semiconductor chips and covers at least a portion of the die-attachment substrate 402, such that the plurality of electrical contacts 404 remains at least partially uncovered for electrical connection thereto. The encapsulant material 416 is preferably an epoxy overcoat or plastic molding, although other suitable means for encapsulating the chips are similarly contemplated (e.g., ceramic), as will be known by those skilled in the art. In the figure, the encapsulant material has been cut away so that the interior of the integrated circuit package can be viewed. In production, however, the encapsulant would completely cover the chips 408, 410.

At least a portion of the methodologies of the present invention may be implemented in an integrated circuit. In forming integrated circuits, a plurality of identical die is typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. An integrated circuit, comprising:
a first semiconductor chip including one or more circuits thereon for performing substantially core logic functions, the first semiconductor chip including a plurality of signal pads for providing electrical connection to the one or more circuits; and
at least a second semiconductor chip including one or more circuits thereon for performing substantially input/output interface functions, the second semiconductor chip including a plurality of signal pads for providing electrical connection to the one or more circuits on the second semiconductor chip, the signal pads on the second semiconductor chip being substantially aligned with and electrically connected to corresponding signal pads on the first semiconductor chip to thereby reduce interconnect parasitics in the integrated circuit;
wherein the first and second semiconductor chips are mutually functionally dependent on one another, such that at least a portion of at least one of the one or more circuits on the first semiconductor chip utilizes at least a portion of at least one of the one or more circuits on the second semiconductor chip, and at least a portion of at least one of the one or more circuits on the second semiconductor chip utilizes at least a portion of at least one of the one or more circuits on the first semiconductor chip, and wherein the first and second semiconductor chips are formed using first and second semiconductor fabrication processes, respectively.

2. The integrated circuit of claim 1, wherein the first semiconductor chip does not include circuitry for performing input/output interface functions.

3. The integrated circuit of claim 1, wherein the signal pads on first semiconductor chip are electrically connected to respective signal pads on the second semiconductor chip using a plurality of corresponding conductive structures.

4. The integrated circuit of claim 1, wherein the signal pads on first semiconductor chip are electrically connected to respective signal pads on the second semiconductor chip using a plurality of corresponding solder bumps.

5. The integrated circuit of claim 1, wherein the first semiconductor chip comprises core logic functional circuitry.

6. The integrated circuit of claim 1, wherein the second semiconductor chip comprises input/output functional circuitry.

7. The integrated circuit of claim 1, wherein the first semiconductor chip comprises substantially digital circuitry and the second semiconductor chip comprises substantially analog circuitry.

8. The integrated circuit of claim 1, wherein at least one of voltage supply and ground connections to the first semiconductor chip are separate from at least one of voltage supply and ground connections, respectively, to the second semiconductor chip.

9. The integrated circuit of claim 1, wherein the first and second semiconductor chips are arranged relative to each other such that an upper surface of the first semiconductor chip faces an upper surface of the second semiconductor chip.

10. The integrated circuit of claim 1, wherein at least one of: (i) one or more parameters of the first semiconductor fabrication process are selectively adjusted to independently optimize a functional performance of the first semiconductor chip; and (ii) one or more parameters of the second semiconductor fabrication process are selectively adjusted to independently optimize a functional performance of the second semiconductor chip.

11. The integrated circuit of claim 1, wherein the one or more circuits on the second semiconductor chip comprises at least one of a serializer/deserializer, a phase-locked loop, an analog-to-digital converter, a digital-to-analog converter, and memory.

12. The integrated circuit of claim 1, wherein the integrated circuit is configured such that a functionality thereof is selectively changed by substituting the first semiconductor chip with another semiconductor chip having a functionality different than that of the first semiconductor chip, the other semiconductor chip including a plurality of signal pads for providing electrical connection to the one or more circuits, the signal pads on the other semiconductor chip being substantially aligned with and electrically connected to corresponding signal pads on the second semiconductor chip, the other semiconductor chip and the second semiconductor chip being mutually functionally dependent on one another.

13. A packaged multiple-die integrated circuit device, comprising:
a die-attachment substrate including a plurality of electrical contacts providing external electrical connection to the package;
a first semiconductor chip including one or more circuits thereon for performing substantially core logic functions, the first semiconductor chip including a plurality of signal pads for providing electrical connection to the one or more circuits;
at least a second semiconductor chip including one or more circuits thereon for performing substantially input/output interface functions, the second semiconductor chip including a plurality of signal pads for providing electrical connection to the one or more circuits on the second semiconductor chip, the signal pads on the second semiconductor chip being substantially aligned with and electrically connected to corresponding signal pads on the first semiconductor chip to thereby reduce interconnect parasitics in the integrated circuit; and
an encapsulant material enclosing the first and second semiconductor chips and covering at least a portion of the die-attachment substrate such that the plurality of electrical contacts remains at least partially uncovered;
wherein the first and second semiconductor chips are mutually functionally dependent on one another, such that at least a portion of at least one of the one or more circuits on the first semiconductor chip utilizes at least a portion of at least one of the one or more circuits on the second semiconductor chip, and at least a portion of at least one of the one or more circuits on the second semiconductor chip utilizes at least a portion of at least one of the one or more circuits on the first semiconductor chip, and wherein the first and second semiconductor chips are formed using first and second semiconductor fabrication processes, respectively.
